(19) United States
(12) Patent Application Publication
(10) Pub. No.: US 2004/0057302 A1
(43) Pub. Date: Mar. 25, 2004

(54) Test circuit of an integrated memory circuit for coding assessment data and method for testing the memory circuit

(76) Inventors: Dirk Fuhrmann, Munchen (DE); Peter Beer, Tutzing (DE)

Correspondence Address: LERNER AND GREENBERG, P.A., POST OFFICE BOX 2480, HOLLYWOOD, FL, 33022-2480, US

(21) Appl. No.: 10/667,256

(22) Filed: Sep. 19, 2003

(30) Foreign Application Priority Data
Sep. 19, 2002 (DE) 102 43 471.9

(51) Int. Cl. G11C 7/00; G11C 29/00

(52) U.S. Cl. 365/200

(57) ABSTRACT

An integrated memory circuit has a memory cell array and a test circuit. The test circuit generates an assessment datum, the assessment datum is dependent on a result of a comparison between a datum read from the memory cell array and a datum previously written to the memory cell array. A coding unit is coupled to the test circuit in order to code a plurality of assessment signals to form a coded test signal, a voltage signal is assigned to the plurality of test data as coded test datum.

### BACKGROUND OF THE INVENTION

### Field of the Invention

The invention relates to an integrated memory circuit having a test circuit that generates assessment data and transmits the latter to a tester unit. The invention furthermore relates to a method for testing the integrated memory circuit with the test circuit.

Integrated memory circuits are generally tested by a test system under various specification-conforming conditions. The testing is usually carried out by writing test data to a memory cell array of the memory circuit and subsequently reading out the data that have been written in. A comparison of the data read out with the data previously written in leads to assessment data which indicate whether the results of the comparison have yielded identity between the written-in and read-out data or a difference between written-in and read-out data. The comparison is usually carried out in a test circuit situated in the integrated memory circuit.

The assessment data thus obtained serve for determining defective memory areas, which are replaced by redundant memory areas in subsequent repair steps in order to repair the integrated memory circuit.

In order to calculate the repair solution, during testing the assessment data have to be transmitted from the integrated memory circuit to a tester unit, in which the optimum repair solution is calculated. The optimum repair solution indicates how the defective memory areas are to be replaced by redundant memory areas since it is possible to replace a defective memory area by redundant word lines or by redundant bit lines.

Usually, a plurality of integrated memory circuits are tested simultaneously in a test system, the parallelism being prescribed by the number of test lines between the tester unit and the number of integrated memory circuits. The time for the testing an integrated memory circuit by the tester unit and the parallelism prescribe the throughput of the test system.

What is a significant determining factor for the time duration for testing an integrated memory circuit is the time duration that is required for transmitting the assessment data from the memory circuit to the tester unit. In order to minimize this time, the assessment data are already compressed in a redundancy-conforming manner in the memory circuit, so that only information about errors in memory areas that are subsequently replaced by a redundant memory area is transmitted. In this case, the compression is based on the fact that bit-fine knowledge of the assessment data is not required, for example, for the repair of memory cells with memory cells from a so-called redundancy area. Consequently, it is possible to combine specific error areas, as a result of which information compression can be achieved. With this type of compression the assessment data are compressed by assessment logic and combined to form an individual assessment datum for each replaceable memory area and forwarded to the tester unit.

However, even the transmission of all the assessment data compressed in a redundancy-conforming manner gives rise to considerable volumes of data to be transmitted, so that even the transmission of assessment data that have already been compressed requires a considerable time.

### SUMMARY OF THE INVENTION

It is accordingly an object of the invention to provide a test circuit of an integrated memory circuit for coding assessment data and a method for testing the memory circuit that overcome the above-mentioned disadvantages of the prior art devices and methods of this general type, which minimizes the test time for testing an integrated memory circuit.

With the foregoing and other objects in view there is provided, in accordance with the invention, an integrated memory circuit. The memory circuit has a memory cell array, and a test circuit connected to the memory cell array. The test circuit generates an assessment datum, the assessment datum is dependent on a result of a comparison between a datum read from the memory cell array and a datum previously written to the memory cell array. A coding unit is coupled to the test circuit for coding a plurality of assessment data to form a coded test signal. The coded test signal is a voltage signal representing the plurality of assessment data and functioning as a coded test datum.

A first aspect of the present invention provides an integrated memory circuit having a memory cell array and a test circuit. The test circuit generates an assessment signal, the assessment signal is dependent on a result of a comparison between a datum read from the memory cell array and a datum previously written to the memory cell array. According to the invention, a coding unit is coupled to the test circuit in order to code a plurality of assessment signals to form a coded test signal. In this case, a voltage signal is assigned to a plurality of assessment signals as a coded test signal, the voltage level of the voltage signal unambiguously describing the plurality of assessment signals.

The coding unit according to the invention thus has the effect of carrying out a coding of the assessment signals, a voltage signal being assigned to the assessment signals. The voltage signal is an analog signal that can assume different voltage levels. It thus contains a higher information density than digitized signals. Consequently, during the testing of the integrated memory circuit, instead of transmitting a plurality of digital assessment signals in parallel or serially via test lines to a tester unit, it is possible to transmit a single analog signal via a test line to the tester unit, which signal contains the information of the plurality of assessment signals.

It may preferably be provided that the coding unit has a digital-to-analog converter circuit, so that the plurality of assessment signals are converted into a voltage level, each voltage level being assigned to a specific pattern of a plurality of assessment signals.

In order to read the coded test signal from the integrated memory circuit, an external terminal is preferably provided, via which the integrated circuit can be connected to a tester unit.

A further aspect of the present invention provides a tester unit in order to receive coded test signals. The tester unit has a decoding circuit, a coded test signal containing a voltage signal that can assume a plurality of signal levels. The decoding circuit is configured in such a way as to assign a respective number of assessment data to the voltage levels of the received voltage signal. What is essential is that each voltage level is respectively assigned a series of assessment data, so that, after the reception of the test data in the tester unit, the assessment data can be assigned to the defective memory areas. In this way, it is possible to provide a tester unit which receives compressed test data and decodes the latter in order to make them available e.g. to an evaluation unit which, in the tester unit, determines a redundancy solution for the optimum replacement of defective memory areas.

The decoding circuit preferably contains an A/D converter circuit in order to convert the voltage levels of the test signal into a digital value containing bits that represent the original assessment data.

A further aspect of the present invention provides a test system having an integrated memory circuit according to the invention, the integrated memory circuit being connected to a tester unit, so that the coded test signal can be transmitted to the tester unit. A test system with which integrated memory circuits can be tested more rapidly is made available in this way.

A further aspect of the present invention provides a method for testing an integrated memory circuit. A datum read from the memory cell array and a datum previously written to the memory cell array are compared with one another during the testing, an assessment signal which is dependent on the result of the comparison being generated. According to the invention, a plurality of assessment signals are coded into a coded test signal, the coded test signal being transmitted to a tester unit, the transmitted coded test signal being decoded to form a plurality of assessment signals.

The method according to the invention has the advantage that the assessment data can be transmitted in compressed fashion to the tester unit, as a result of which it is possible, on the one hand, to save test lines, in order thus to increase the parallelism of the test system, and, on the other hand, to increase the transmission speed for transmitting the assessment data, so that more assessment data can be communicated to the tester unit within a specific time.

Other features which are considered as characteristic for the invention are set forth in the appended claims.

Although the invention is illustrated and described herein as embodied in a test circuit of an integrated memory circuit for coding assessment data and a method for testing the memory circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a test system according to the invention;

FIG. 2 is a circuit diagram of a coding unit for an integrated memory circuit according to the invention;

FIG. 3 is a table representing the coding of assessment data into different voltage levels; and

FIG. 4 is a block diagram of a decoder circuit for a tester unit according to the invention.

### DESCRIPTION OF THE PREFERRED EMBODIMENTS

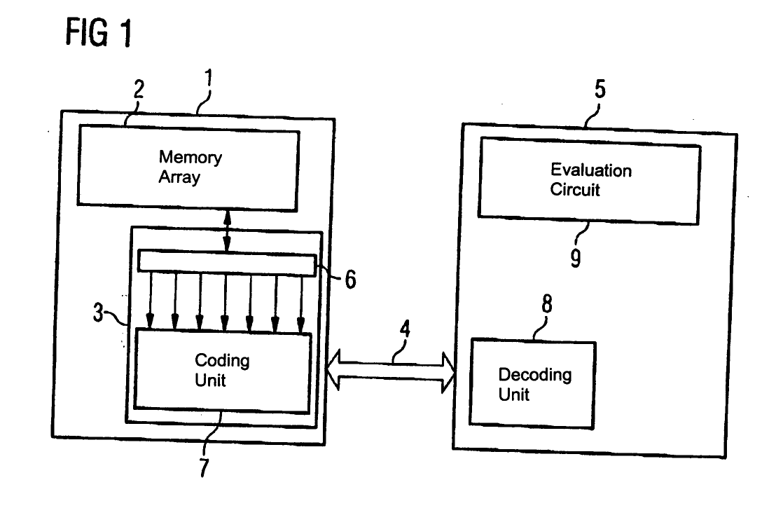

Referring now to the figures of the drawing in detail and first, particularly, to FIG. 1 thereof, there is shown a block diagram of a test system according to the invention. The test system has an integrated memory circuit 1, in particular a DRAM memory circuit having a memory cell array 2 and a test circuit 3. The integrated memory circuit 1 is connected to a tester unit 5 via a signal bus 4. Via the signal bus 4, address data and control data can be transmitted from the tester unit 5 to the integrated memory circuit 1 and assessment data can be transmitted from the integrated memory circuit 1 to the tester unit 5.

The test circuit 3 has a comparator circuit 6, which serves for comparing the data written to the memory cell array 2 with the data read from the memory cell array 2 and for generating assessment data as the result, the assessment data being dependent on whether the written-in and read-out data are identical to or different from one another. Thus, by way of example, an assessment datum has the value “0” if the written-in and read-out data are identical and the value “1” if the written-in and read-out data are different.

Usually, the data are compared with one another bit by bit or memory area by memory area, thereby generating assessment data that indicate bit by bit whether the written-in and read-out data are identical to or different from one another. The assessment data are forwarded to a coding unit 7, which performs a compression of the assessment data.

After the assessment data has been compressed, the coded test data thus determined are communicated via the signal bus 4 to the tester unit 5, where the coded test data are decoded in a decoding unit 8 and fed to an evaluation circuit 9, which determines a redundancy solution from the assessment data.

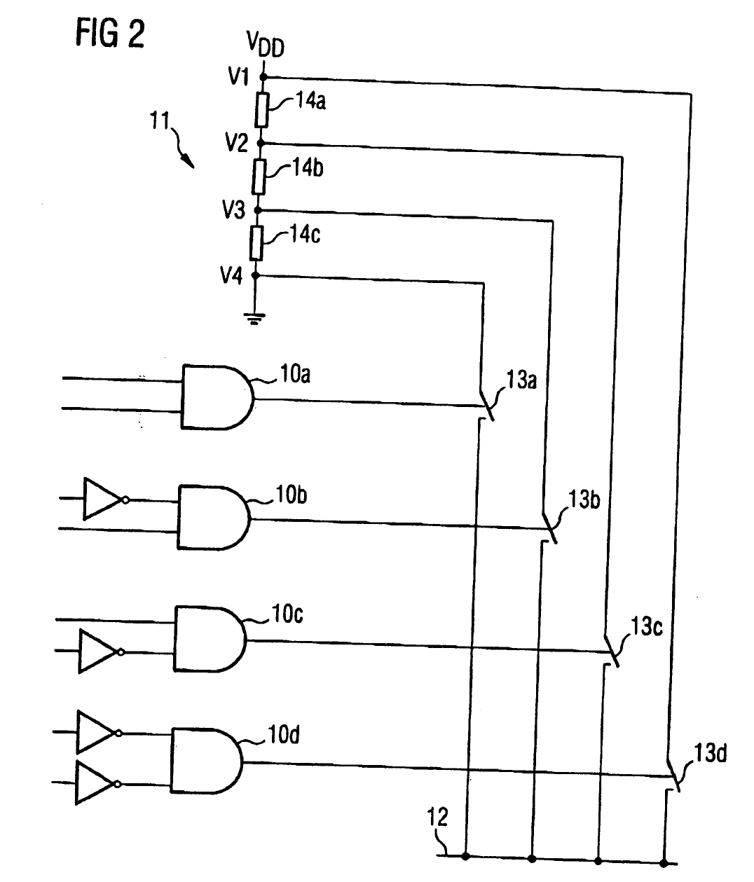

FIG. 2 illustrates a circuit diagram of a coding unit for the integrated memory circuit according to the invention. The coding unit illustrated essentially represents a two-bit digital-to-analog converter that converts two bits of data into an analog voltage value. For the sake of clarity, the illustration of the coding unit is restricted to a two-bit digital-to-analog converter. However, it is conceivable for an arbitrary number of bits to be coded in this way. This is limited only by the resolution accuracy of the decoding unit 8 in the tester unit 5 and by the susceptibility to interference of the signal lines of the signal bus 4.

The coding unit 7 is essentially constructed in two parts for each possible bit combination of the assessment data to be coded. A first part essentially contains an AND gate 10a-10d, to whose inputs the assessment data to be coded are applied either in non-inverted form or in a manner inverted by an inverter. The output of the respective AND gate leads to a control input, a switch 13a-13d, the respective switch 13a-13d being closed in the event of a high state of the output of the respective AND gate 10a-10d, so that a voltage generated by a voltage divider 11 is applied to an output line 12. The AND gates 10a-10d are connected in such a way that only one of the switches 13a-13d is closed in each case. Each of the switches 13a-13d switches a voltage potential onto the output line 12 which unambiguously determines the bit combination present, i.e. it differs from the other voltage potentials.

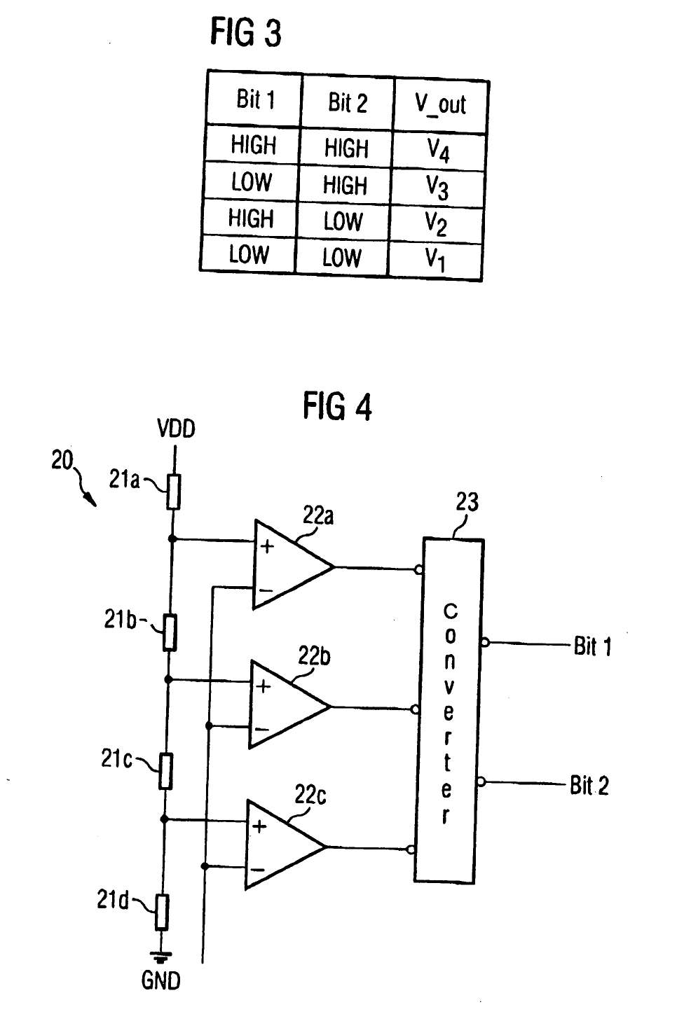

Thus, the first bit and the second bit are applied in non-inverted form to the inputs of the first AND gate 10a, the first bit and the second bit are applied in inverted and non-inverted form, respectively, to the second AND gate 10b, the first bit and the second bit are applied in non-inverted and inverted form, respectively, to the third AND gate 10c, and the first bit and the second bit are applied in inverted form to the fourth AND gate 10d. In this way, the four states which can be represented by the first bit and the second bit can be coded into four voltage levels. This is illustrated in the table according to FIG. 3.

Such a coding unit can be extended arbitrarily and thus be used for coding two, three, four or more assessment data.

The voltage divider 11 is essentially constructed by a series of resistors 14a, 14b, 14c, between which various predefined voltage levels can be tapped off. The series of resistors 14a, 14b, 14c is disposed between a supply voltage potential VDD and a ground potential GND. The supply voltage potential VDD represents the first voltage level V1 and the ground potential GND represents the fourth voltage level V4. The second voltage level V2 can be tapped off the node between the first resistor 14a and the second resistor 14b, and the third voltage level V3 can be tapped off at the node between the second resistor 14b and the third resistor 14c. The first voltage level V1 is connected to a terminal of the first switch 13a, the second voltage level V2 is connected to a terminal of the second switch 13b, the third voltage level V3 is connected to a terminal of the third switch 13c, and the fourth voltage level V4 is connected to a terminal of the fourth switch 13d.

Such a voltage divider circuit can likewise be extended in the coding of more than two bits, so that not only four, but 8, 16 and more voltage levels can be generated.

FIG. 4 illustrates a circuit diagram of the decoding unit 8, which may be provided in the tester unit 5, for example. The decoding unit 8 is essentially an analog-to-digital converter circuit, with a resolution that corresponds at least to the number of assessment data compressed in the test signal. It is provided with a second voltage divider circuit 20 having four resistors 21a, 21b, 21c, 21d connected in series. The first and fourth resistors 21a, 21d have respectively half the resistance of respectively the second and third resistors 21b, 21c. The node between the first resistor 21a and the second resistor 21b is connected to a non-inverting input of a first comparator. The node between the second resistor 21b and the third resistor 21c is connected to the non-inverting input of a second comparator circuit 21b, and the node between the third resistor 21c and the fourth resistor 21d is connected to the non-inverting input of a third comparator circuit 22c. The coded test signal is applied to the inverting inputs of the first, second and third comparator circuits 22a, 22b, 22c. The comparator circuits 22a, 22b, 22c are in each case connected by an output to a converter circuit 23 having two outputs. Signal bits coded in the coded test signal are present at the two outputs during the decoding.

The converter circuit 23 decodes the three signals present at the outputs of the comparator circuits 22a, 22b, 22c, thereby recovering the first and second bits of the original assessment data. Depending on the voltage level of the coded test signal, none, one or all of the outputs of the comparator circuits 22a, 22b, 22c have a high state. If the voltage level is 0 V or the voltage V1, then all the outputs of the comparator circuit 22 are at a high level, while in the event of a voltage level of the coded test signal with the magnitude of the supply voltage or the voltage V4, then all three outputs of the comparator circuits are in a low state.

In this way, it is possible to provide a decoding unit 8 which is able to process a coded test signal in which four states which can be represented by two bits are decoded, in which the voltage level ranges of the defined voltage levels of the coded test signal are respectively assigned to a state defined by a two-bit combination by the first bit and the second bit.

The invention relates to compressing an arbitrary number of cell signals to form a single item of error information and in transferring it from the integrated memory circuit to an external tester unit.

The invention furthermore contains the tester unit having the decoding circuit that is able to decode the compressed error information, i.e. to assign a series of assessment data to the voltage levels of the coded test signal. The compression enables a high information transmission rate per unit time.

The coded test signals that have been generated with the aid of the coding unit illustrated in FIG. 2 are preferably transmitted to the tester unit 5 within a clock cycle. In this way, the transmission of the assessment data can be accelerated by a factor of 4 since information from four-bit assessment data is transmitted with the aid of a coded test signal that can be transmitted per clock cycle.

The decoding unit 8 may either be disposed within the tester unit or be connected upstream of the tester unit, so that there is no need to modify a conventional tester unit. Consequently, the tester lines disposed between the integrated memory circuit and the tester unit are not connected to the tester unit directly, but rather via the decoding unit 8, at whose outputs the decoded assessment data can then be tapped off. In this way it is possible to avoid intervention in the tester devices of complex construction.

We claim:

1. An integrated memory circuit, comprising:
a memory cell array;
a test circuit connected to said memory cell array, said test circuit generating an assessment datum, the assessment datum being dependent on a result of a comparison between a datum read from said memory cell array and a datum previously written to said memory cell array; and.
a coding unit coupled to said test circuit for coding a plurality of assessment data to form a coded test signal, the coded test signal being a voltage signal representing the plurality of assessment data and functioning as a coded test datum.

2. The integrated memory circuit according to claim 1, wherein said coding unit has a digital-to-analog converter circuit.

3. The integrated memory circuit according to claim 2, wherein said coding unit generates a plurality of voltage levels, so that a respective voltage level is assigned to a specific pattern of the plurality of assessment data.

4. The integrated memory circuit according to claim 1, further comprising an external terminal for reading the coded test datum from the integrated memory circuit.

5. The integrated memory circuit according to claim 4, wherein the voltage signal can be read out within a clock cycle.

6. A tester unit for receiving coded assessment data, comprising:
a decoding circuit for receiving a coded test signal containing a voltage signal which can assume a plurality of signal levels, said decoding circuit generating a respective pattern of assessment data in response to a voltage level of the voltage signal received.

7. The tester unit according to claim 6, wherein said decoding circuit has an analog/digital converter circuit.

8. A test system, comprising:
an integrated memory circuit, containing:
a memory cell array;
a test circuit connected to said memory cell array, said test circuit generating an assessment datum, the assessment datum being dependent on a result of a comparison between a datum read from said memory cell array and a datum previously written to said memory cell array; and
a coding unit coupled to said test circuit for coding a plurality of assessment data to form a coded test signal, the coded test signal being a voltage signal representing the plurality of assessment data and functioning as a coded test datum;
a tester unit connected to said integrated memory circuit so that the coded test datum can be transmitted to said tester unit.

9. The test system according to claim 8, wherein said tester unit contains a decoding circuit receiving the coded test signal containing the voltage signal which can assume a plurality of signal levels, said decoding circuit generating a respective pattern of assessment data in response to a voltage level of the voltage signal.

10. A method for testing an integrated memory circuit having a memory cell array, which comprises the steps of:
comparing a datum read from the memory cell array with a datum previously written to the memory cell array;
generating an assessment datum in dependence on a result of the comparing step;
coding a plurality of assessment data into a coded test datum;
transmitting the coded test datum to a tester unit; and
decoding the coded test datum back into the plurality of assessment data.

11. The method according to claim 10, which further comprises performing the coding of the assessment data such that the coded test datum can have one of a plurality of voltage levels, each of the voltage levels representing a specific pattern of assessment data.
